(19) United States
(12) Patent Application Publication
(10) Pub. No.: US 2019/0390322 A1
(43) Pub. Date: Dec. 26, 2019

(54) MATERIAL DEPOSITION ARRANGEMENT, VACUUM DEPOSITION SYSTEM AND METHODS THEREFOR

(71) Applicant: Applied Materials, Inc., Santa Clara, CA (US)

(72) Inventors: Jose Manuel DIEGUEZ-CAMPO, Hanau (DE); Harald WURSTER, Mömbris (DE); Uwe SCHÜSSLER, Aschaffenburg (DE)

(21) Appl. No.: 15/749,023

(22) PCT Filed: Mar. 17, 2017
(86) PCT No.: PCT/EP2017/056377

§ 371 Date: Jan. 30, 2018

(51) Int. Cl. C23C 14/24

(52) U.S. Cl. CPC C23C 14/243; H01L 51/001

(57) ABSTRACT

A material deposition arrangement for depositing a material on a substrate in a vacuum deposition chamber is described. The material deposition arrangement includes at least one material deposition source having a crucible configured to evaporate the material, a distribution assembly configured for providing the evaporated material to the substrate, and a force application device configured for applying a contact force at a connection between the crucible and the distribution assembly.

### TECHNICAL FIELD

Embodiments of the present disclosure relate to deposition apparatuses for depositing one or more layers, particularly layers including organic materials therein, on a substrate. In particular, embodiments of the present disclosure relate to material deposition arrangements for depositing evaporated material on a substrate in a vacuum deposition chamber, vacuum deposition systems and methods therefor, particularly for OLED manufacturing.

### BACKGROUND

Organic evaporators are a tool for the production of organic light-emitting diodes (OLED). OLEDs are a special type of light-emitting diode in which the emissive layer comprises a thin-film of certain organic compounds. Organic light emitting diodes (OLEDs) are used in the manufacture of television screens, computer monitors, mobile phones, other hand-held devices, etc., for displaying information. OLEDs can also be used for general space illumination. The range of colors, brightness, and viewing angles possible with OLED displays is greater than that of traditional LCD displays because OLED pixels directly emit light and do not involve a back light. Therefore, the energy consumption of OLED displays is considerably less than that of traditional LCD displays. Further, the fact that OLEDs can be manufactured onto flexible substrates results in further applications.

The functionality of an OLED depends on the coating thickness of the organic material. This thickness has to be within a predetermined range. In the production of OLEDs, there are technical challenges with respect to the deposition of evaporated materials in order to achieve high resolution OLED devices. Further, decreasing processing times and facilitating maintenance of deposition systems are of high relevance.

Accordingly, there is a continuing demand for providing improved material deposition arrangements, vacuum deposition systems and methods therefor.

### SUMMARY

In light of the above, a material deposition arrangement, a vacuum deposition system, a method for assembling a material deposition arrangement and a method for exchanging a crucible of a material deposition arrangement according to the independent claims are provided. Further aspects, benefits, and features of the present disclosure are apparent from the claims, the description, and the accompanying drawings.

According to an aspect of the present disclosure, a material deposition arrangement for depositing a material on a substrate in a vacuum deposition chamber is provided. The material deposition arrangement includes at least one material deposition source having a crucible configured to evaporate the material, a distribution assembly configured for providing the evaporated material to the substrate, and a force application device configured for applying a contact force at a connection between the crucible and the distribution assembly.

According to another aspect of the present disclosure, a material deposition arrangement for depositing a material on a substrate in a vacuum chamber is provided. The material deposition arrangement includes a first deposition source having a first crucible configured to evaporate a first material, a first distribution assembly configured for providing the evaporated material to the substrate, and a first force application device configured for applying a contact force at a connection between the first crucible and the first distribution assembly. Further, the material deposition arrangement includes a second deposition source having a second crucible configured to evaporate a second material, a second distribution assembly configured for providing the evaporated material to the substrate, and a second force application device configured for applying a contact force at a connection between the second crucible and the second distribution assembly.

According to another aspect of the present disclosure, a vacuum deposition system is provided. The vacuum deposition system includes a vacuum deposition chamber, a material deposition arrangement according to any embodiments described herein in the vacuum deposition chamber, and a substrate support configured for supporting a substrate during material deposition.

According to yet another aspect of the present disclosure, a method for assembling a material deposition arrangement having at least one material deposition source with a crucible and a distribution assembly is provided. The method includes: inserting the crucible into a compartment of the at least one material deposition source; fixing a crucible holding arrangement holding the crucible to a wall of the at least one material deposition source; and applying a contact force at a connection between the crucible and the distribution assembly.

According to a further aspect of the present disclosure, a method for exchanging a crucible of a material deposition arrangement having at least one material deposition source with the crucible and a distribution assembly is provided. The method includes: detaching a crucible holding arrangement holding the crucible from a wall of the at least one material deposition source; releasing a contact force at a connection between the crucible and the distribution assembly; removing the crucible from a compartment of the at least one material deposition source; and replacing the crucible by a new crucible.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic cross-sectional side view of a material deposition arrangement according to embodiments described herein;

FIG. 2A shows a schematic cross-sectional side view of a material deposition arrangement according to further embodiments described herein;

FIG. 2B shows a schematic cross-sectional side view of a material deposition arrangement in which the crucible holding arrangement is disassembled from the material deposition source;

FIG. 3A shows a detailed schematic cross-sectional side view of a lower portion of a material deposition arrangement according to embodiments described herein, wherein the crucible holding arrangement is disassembled from the material deposition source;

FIG. 3B shows a detailed schematic cross-sectional side view of a lower portion of a material deposition arrangement according to embodiments described herein, wherein the crucible holding arrangement is fixed to the material deposition source;

FIG. 4 shows a schematic side view of a material deposition arrangement according to further embodiments described herein;

FIG. 5 shows a more detailed schematic cross-sectional top view of a material deposition arrangement according to further embodiments described herein as exemplarily shown in FIG. 4;

FIG. 6 shows a schematic view of vacuum deposition system according to embodiments described herein with a valve being in an open state;

FIG. 7 shows a flow chart illustrating a method for assembling a material deposition arrangement having at least one material deposition source with a crucible and a distribution assembly according to embodiments described herein; and

FIG. 8 shows a flow chart illustrating a method for exchanging a crucible of a material deposition arrangement having at least one material deposition source with the crucible and a distribution assembly according to embodiments described herein.

### DETAILED DESCRIPTION OF EMBODIMENTS

Reference will now be made in detail to the various embodiments, one or more examples of which are illustrated in each figure. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, the same reference numbers refer to the same or to similar components. Generally, only the differences with respect to the individual embodiments are described. Unless specified otherwise, the description of a part or aspect in one embodiment can apply to a corresponding part or aspect in another embodiment as well.

Before various embodiments of the present disclosure are described in more detail, some aspects with respect to some terms and expressions used herein are explained.

In the present disclosure, a “material deposition arrangement” is to be understood as an arrangement configured for material deposition on a substrate as described herein. In particular, a “material deposition arrangement” can be understood as an arrangement configured for deposition of organic materials, e.g. for OLED display manufacturing, on large area substrates. For instance, a “large area substrate” can have a main surface with an area of 0.5 m² or larger, particularly of 1 m² or larger. In some embodiments, a large area substrate can be GEN 4.5, which corresponds to about 0.67 m² of substrate (0.73×0.92 m), GEN 5, which corresponds to about 1.4 m² of substrate (1.1 m×1.3 m), GEN 7.5, which corresponds to about 4.29 m² of substrate (1.95 m×2.2 m), GEN 8.5, which corresponds to about 5.7 m² of substrate (2.2 m×2.5 m), or even GEN 10, which corresponds to about 8.7 m² of substrate (2.85 m×3.05 m). Even larger generations such as GEN 11 and GEN 12 and corresponding substrate areas can similarly be implemented.

The term “substrate” as used herein may particularly embrace substantially inflexible substrates, e.g., a wafer, slices of transparent crystal such as sapphire or the like, or a glass plate. However, the present disclosure is not limited thereto, and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.5 mm or below, wherein the flexibility of the substantially inflexible substrate is small in comparison to the flexible substrates. According to embodiments described herein, the substrate may be made of any material suitable for material deposition. For instance, the substrate may be made of a material selected from the group consisting of glass (for instance soda-lime glass, borosilicate glass etc.), metal, polymer, ceramic, compound materials, carbon fiber materials or any other material or combination of materials which can be coated by a deposition process.

In the present disclosure, a “vacuum deposition chamber” is to be understood as a chamber configured for vacuum deposition. The term “vacuum”, as used herein, can be understood in the sense of a technical vacuum having a vacuum pressure of less than, for example, 10 mbar. Typically, the pressure in a vacuum chamber as described herein may be between 10⁻⁵ mbar and about 10⁻⁸ mbar, more typically between 10⁻⁵ mbar and 10⁻⁷ mbar, and even more typically between about 10⁻⁶ mbar and about 10⁻⁷ mbar. According to some embodiments, the pressure in the vacuum chamber may be considered to be either the partial pressure of the evaporated material within the vacuum chamber or the total pressure (which may approximately be the same when only the evaporated material is present as a component to be deposited in the vacuum chamber). In some embodiments, the total pressure in the vacuum chamber may range from about 10⁻⁴ mbar to about 10⁻⁷ mbar, especially in the case that a second component besides the evaporated material is present in the vacuum chamber (such as a gas or the like).

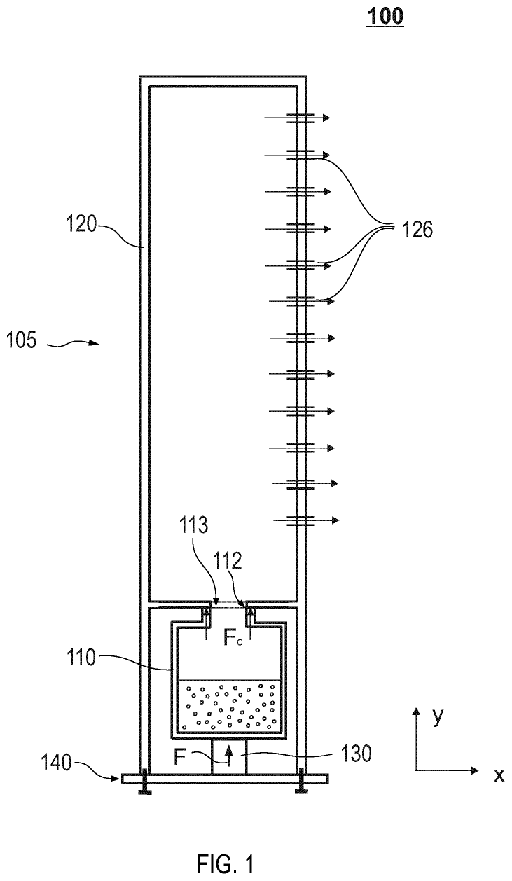

In the present disclosure, a “material deposition source” can be understood as a device or assembly configured for providing a source of material to be deposited on a substrate. In particular, a “material deposition source” may be understood as a device or assembly having a crucible configured to evaporate the material to be deposited and a distribution assembly configured for providing the evaporated material to the substrate. The expression “a distribution assembly configured for providing the evaporated material to the substrate” may be understood in that the distribution assembly is configured for guiding gaseous source material in a deposition direction, exemplarily indicated in FIG. 1 by arrows through the outlets 126. Accordingly, the gaseous source material, for example a material for depositing a thin film of an OLED device, is guided within the distribution assembly and exits the distribution assembly through one or more outlets 126. For example, the one or more outlets of the distribution assembly, e.g. a distribution pipe, can be nozzles extending along an evaporation direction. Typically, the evaporation direction is essentially horizontal, e.g. the horizontal direction may correspond to the x-direction indicated in FIG. 1.

In the present disclosure, a “crucible” can be understood as a device having a reservoir for the material to be evaporated by heating the crucible. Accordingly, a “crucible” can be understood as a source material reservoir which can be heated to vaporize the source material into a gas by at least one of evaporation and sublimation of the source material. Typically, the crucible includes a heater to vaporize the source material in the crucible into a gaseous source material. For instance, initially the material to be evaporated can be in the form of a powder. The reservoir can have an inner volume for receiving the source material to be evaporated, e.g. an organic material. For example, the volume of the crucible can be between 100 cm³ and 3000 cm³, particularly between 700 cm³ and 1700 cm³, more particularly 1200 cm³. In particular, the crucible may include a heating unit configured for heating the source material provided in the inner volume of the crucible up to a temperature at which the source material evaporates. For instance, the crucible may be a crucible for evaporating organic materials, e.g. organic materials having an evaporation temperature of about 100° C. to about 600° C.

In the present disclosure, a “distribution assembly” can be understood as an assembly configured for providing evaporated material, particularly a plume of evaporated material, from the distribution assembly to the substrate. For example, the distribution assembly may include a distribution pipe which can be an elongated cube. For instance, a distribution pipe as described herein may provide a line source with a plurality of openings and/or nozzles which are arranged in at least one line along the length of the distribution pipe.

Accordingly, the distribution assembly can be a linear distribution showerhead, for example, having a plurality of openings (or an elongated slit) disposed therein. A showerhead as understood herein can have an enclosure, hollow space, or pipe, in which the evaporated material can be provided or guided, for example from the evaporation crucible to the substrate. According to embodiments which can be combined with any other embodiments described herein, the length of the distribution pipe may correspond at least to the height of the substrate to be deposited. In particular, the length of the distribution pipe may be longer than the height of the substrate to be deposited, at least by 10% or even 20%. For example, the length of the distribution pipe can be 1.3 m or above, for example 2.5 m or above. Accordingly, a uniform deposition at the upper end of the substrate and/or the lower end of the substrate can be provided. According to an alternative configuration, the distribution assembly may include one or more point sources which can be arranged along a vertical axis.

Accordingly, a “distribution assembly” as described herein may be configured to provide a line source extending essentially vertically. In the present disclosure, the term “essentially vertically” is understood particularly when referring to the substrate orientation, to allow for a deviation from the vertical direction of 10° or below. This deviation can be provided because a substrate support with some deviation from the vertical orientation might result in a more stable substrate position. Yet, the substrate orientation during deposition of the organic material is considered essentially vertical, which is considered different from the horizontal substrate orientation. Accordingly, the surface of the substrates can be coated by a line source extending in one direction corresponding to one substrate dimension and a translational movement along the other direction corresponding to the other substrate dimension.

In the present disclosure, a “force application device” is to be understood as a device which is configured for applying or generating a mechanical force. In particular, a “force application device” can be understood as a device which is configured for applying or generating a mechanical contact force, e.g. between a crucible and a distribution assembly as described herein. For instance, the force application device may be a passive mechanical element, e.g. a spring. In particular, it is to be understood that a passive mechanical element, e.g. a compressed spring, can be used to store potential energy, e.g. spring energy, which can be used to exert or apply a mechanical force. Alternatively, the force application device may be an active mechanical element, e.g. an actuator. For instance, a pneumatic actuator, a hydraulic actuator or an electric actuator may be used as an active mechanical element.

FIG. 1 shows a schematic sectional view of a material deposition arrangement 100 according to embodiments described herein. In particular, the material deposition arrangement is configured for depositing a material on a substrate in a vacuum deposition chamber. As exemplarily shown in FIG. 1, the material deposition arrangement includes at least one material deposition source 105 having a crucible 110 configured to evaporate the material. Further, the material deposition arrangement includes a distribution assembly 120 configured for providing the evaporated material to the substrate. As exemplarily shown in FIG. 1, the distribution assembly 120 of the at least one deposition source may include a distribution pipe with one or more outlets 126 provided along the length of the distribution pipe. Typically, the distribution assembly 120 is connected to the crucible 110. For instance, the distribution assembly can be directly connected to the crucible. Particularly, the distribution assembly and the crucible may have at least one contact surface at which the distribution assembly is in contact with the crucible.

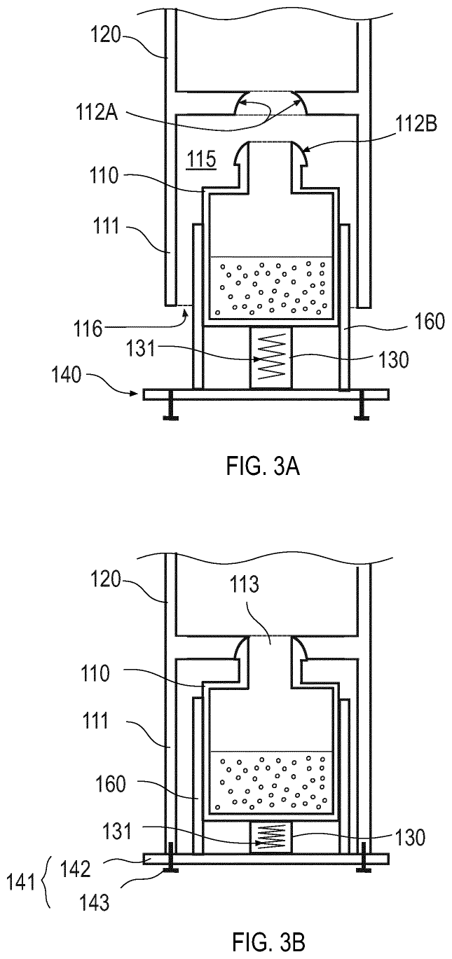

In particular, an opening 113 may be provided at the bottom of the distribution assembly 120. For instance, the opening 113 provided at the bottom of the distribution assembly 120 can be arranged and configured to allow fluid communication with the crucible 110, for instance via an opening provided in a top wall of the crucible. For example, the diameter D of the opening (see FIG. 3A), can be selected from a range having a lower limit of D=10 mm, particularly a lower limit of D=15 mm, more particularly a lower limit of D=20, and an upper limit of D=100 mm, particularly an upper limit of D=80 mm, more particularly an upper limit of D=50 mm. For instance, the diameter D of the opening can be D=45 mm.

Typically, the crucible and the distribution assembly are configured to be connectable to each other such that fluid communication between the crucible and the distribution assembly is confined to the area of the respective openings, e.g. a connection of the opening provided at the bottom of the distribution assembly with the opening provided in a top wall of the crucible. Accordingly, in an assembled state, a bottom portion of the distribution assembly can be in contact with a top portion of the crucible.

Further, as exemplarily shown in FIG. 1, the material deposition arrangement 100 typically includes a force application device 130 configured for applying a contact force F_{c} at a connection 112 between the crucible 110 and the distribution assembly 120. In particular, the force application device 130 can be provided below the crucible 110, as exemplarily shown in FIG. 1. More specifically, the force application device may be arranged between a crucible holding arrangement 140 and a bottom of the crucible 110. For example, the force application device 130 can be connected with the one end to the crucible holding arrangement 140 and with the other end to the bottom of the crucible 110. As exemplarily indicated with the arrow in FIG. 1, the force application device is configured for applying a force F in a direction towards a connection 112 between the crucible 110 and the distribution assembly 120. For instance, the force F applicable by the force application device can be a force in a substantially vertical direction, e.g. in a direction opposite to the gravitational force. The vertical direction is exemplarily indicated in FIG. 1 by the direction of the y-coordinate. For instance, the force application device 130 can be configured to provide a force of 100 N, e.g. a contact force at a connection between the crucible and the distribution assembly.

Accordingly, beneficially a material deposition arrangement is provided which provides for an improved sealing between the crucible and the distribution assembly. In particular, by providing a material deposition arrangement having a force application device as described herein provides for the possibility of facilitated crucible exchange. Further, beneficially a high quality sealing between the crucibles and the distribution assembly can be provided independent of crucible size. In other words, the force application device can be configured such that a contact force at the interface, e.g. the connection 112, between the crucible and the distribution assembly is independent of the size of the employed crucible.

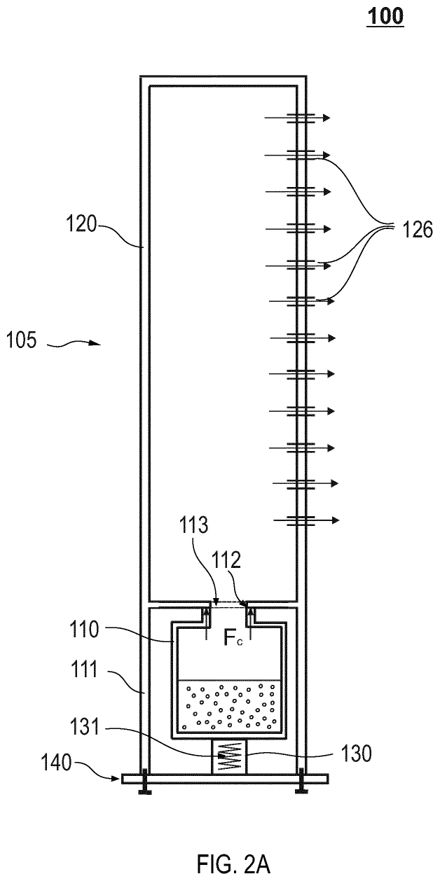

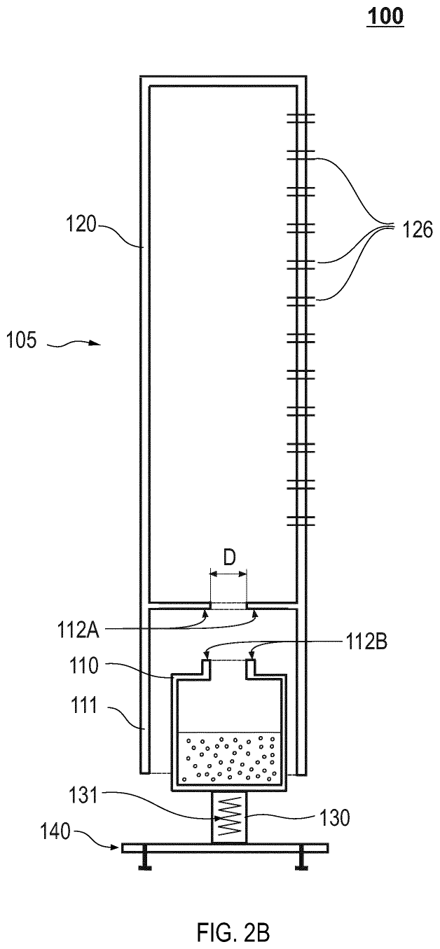

With exemplary reference to FIGS. 2A and 2B, according to embodiments which can be combined with any other embodiment described herein, the at least one material deposition source 105 may include a crucible holding arrangement 140 configured to be detachably connected to a wall 111 of the at least one material deposition source. FIG. 2A shows the material deposition arrangement in an assembled state, whereas FIG. 2B shows the material deposition arrangement in a state in which the crucible holding arrangement 140 is disassembled from the wall 111 of the at least one material deposition source 105. As can be seen by a comparison of FIG. 2A with FIG. 2B, upon demounting the crucible holding arrangement 140 from the at least one material deposition source 105, the force application device may expand, for example in the case of a force application device having a spring as described herein. Accordingly, according to embodiments which can be combined with any other embodiment described herein, the force application device 130 may include at least one spring 131 for applying the contact force. In particular, not explicitly shown, the at least one spring may include two springs, three springs, four springs, or more springs. For instance, three springs may beneficially be applied for a crucible having a substantially triangular cross-section. In particular, in each corner of a triangular bottom wall of a crucible having a triangular cross-section, a spring can be provided. Accordingly, in the case of a crucible having a substantially rectangular cross-section, a force application device including four springs can be advantageous, e.g. one spring in each corner of a rectangular a bottom wall of a crucible having a rectangular cross-section. Thus, beneficially a homogeneous contact force at a connection between the crucible and the distribution assembly may be provided.

In particular, as exemplarily shown in FIGS. 1, 2A and 2B, according to embodiments which can be combined with any other embodiment described herein, the force application device 130 may be connected to the crucible holding arrangement 140. For instance, the crucible holding arrangement 140 may include a mounting assembly 141 configured for mounting the crucible holding arrangement to the wall of the at least one material deposition source, as exemplarily shown in FIG. 3B. In particular, the mounting assembly 141 can include a mounting plate 142 and one or more fixation elements 143, such as a screw. Typically, the wall 111 of the material deposition source to which the holding arrangement is mountable includes corresponding receptions for the one or more fixation elements 143.

Accordingly, with exemplary reference to FIGS. 3A and 3B, according to embodiments which can be combined with any other embodiment described herein, the at least one material deposition source 105 may include a crucible compartment 115 having a closable opening 116 configured for exchanging the crucible. Such a configuration can in particular be beneficial for facilitated maintenance as well as for facilitated and quick crucible exchange or replacement.

With exemplary reference to FIGS. 3A and 3B, according to embodiments which can be combined with any other embodiment described herein, the crucible holding arrangement may include a heating arrangement 160 configured to provide heat to the crucible for evaporating the material. In particular, as exemplarily shown in FIGS. 3A and 3B, the heating arrangement 160 can be configured such that at least a portion of the crucible can be placed inside the heating arrangement. For example, the heating arrangement may be configured for holding or supporting the crucible in a lateral direction. Typically, the heating arrangement can be configured for providing heat to the crucible for evaporating organic materials, e.g. organic materials having an evaporation temperature of about 100° C. to about 600° C., provided inside the crucible.

Accordingly, according to embodiments which can be combined with any other embodiment described herein, the force application device 130 can be made of a material having a heat resistance of up to a temperature of at least 200° C., particularly of at least 400° C., more particularly of at least 600° C., such as at least 750° C. For instance, the force application device, e.g. the at least one spring 131, can include or be made of an austenitic nickel-chromium-based superalloy, such as Inconel.

With exemplary reference to FIGS. 2B and 3A, according to embodiments which can be combined with any other embodiment described herein, the connection between the crucible 110 and the distribution assembly may be provided by a first contact surface 112A of the distribution assembly and a mating second contact surface 112B of the crucible. For instance, as exemplarily shown in FIG. 3A, the first contact surface 112A can be a concave contact surface and the mating second contact surface 112B may be a mating convex contact surface. Accordingly, beneficially an improved sealing between the crucible and the distribution assembly can be provided.

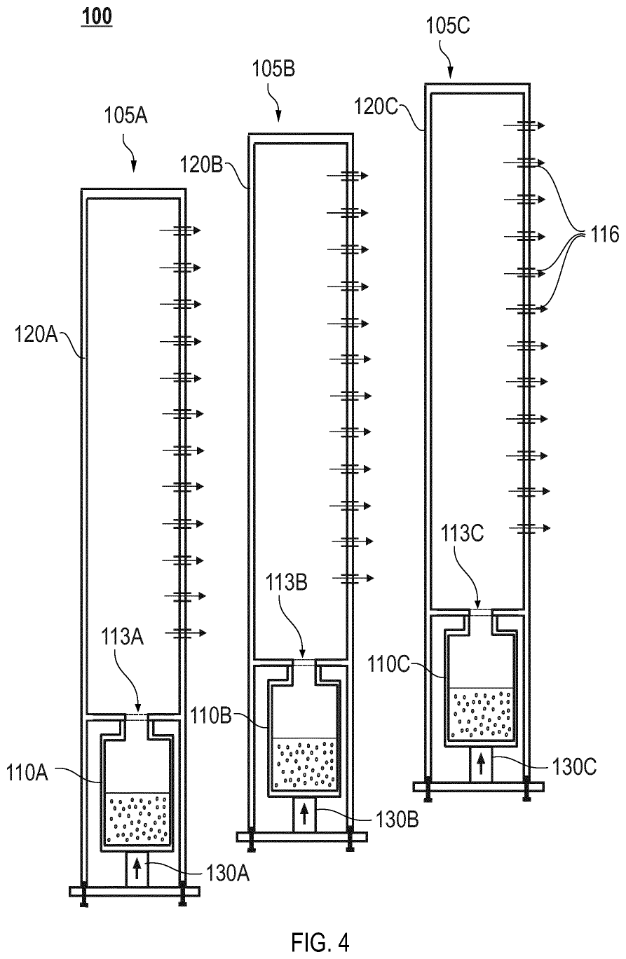

According to embodiments which can be combined with other embodiments described herein, the at least one material deposition source may include a first deposition source 105A and a second deposition source 105B. Additionally, a third deposition source 105C may be provided, as exemplarily shown in FIG. 4. The first deposition source 105A includes a first crucible 110A configured to evaporate a first material, a first distribution assembly 120A configured for providing the first evaporated material to the substrate, and a first force application device 130A configured for applying a contact force at a connection between the first crucible 110A and the first distribution assembly 120A. The second deposition source 105B includes a second crucible 110B configured to evaporate a second material, a second distribution assembly 120B configured for providing the second evaporated material to the substrate, and a second force application device 130B configured for applying a contact force at a connection between the second crucible 110B and the second distribution assembly 120B. The third deposition source 105C includes a third crucible 110C configured to evaporate a third material, a third distribution assembly 120C configured for providing the third evaporated material to the substrate, and a third force application device 130C configured for applying a contact force at a connection between the third crucible 110C and the third distribution assembly 120C.

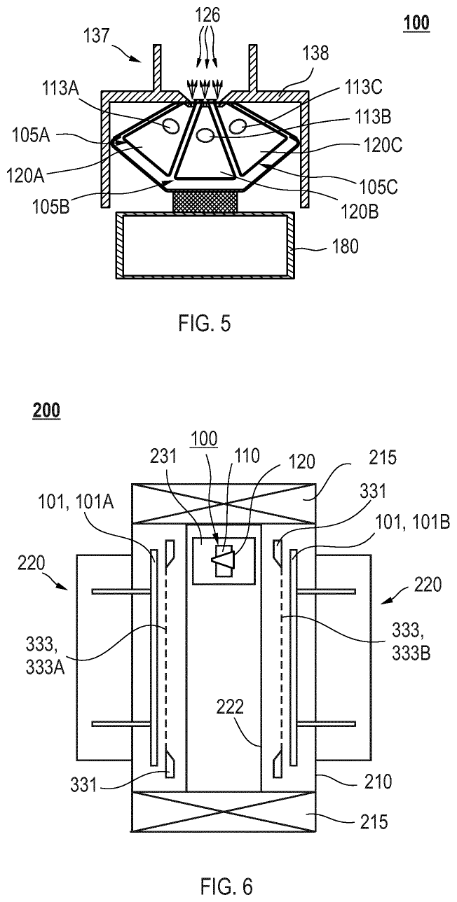

FIG. 5 shows a more detailed schematic cross-sectional top view of a material deposition arrangement according to further embodiments described herein as exemplarily shown in FIG. 4. In particular, FIG. 5 shows a cross-sectional top view of a material deposition arrangement including a first deposition source 105A, a second deposition source 105B, and a third deposition source 105C.

Accordingly, from FIGS. 4 and 5, it is to be understood that three distribution assemblies, e.g. distribution pipes, and corresponding evaporation crucibles can be provided next to each other. Accordingly, a material deposition arrangement may be provided as an evaporation source array, e.g. wherein more than one kind of material can be evaporated at the same time. Further, an evaporation source array having three distribution assemblies and corresponding evaporation crucibles configured for evaporating organic material may also be referred to as a triple organic source.

In particular, with exemplary reference to FIG. 5, the at least one material deposition source of the material deposition arrangement 100 may include three deposition sources, e.g. a first deposition source 105A, a second deposition source 105B, and a third deposition source 105C. Typically, each deposition source includes a distribution assembly as described herein, a crucible as described herein, and a force application device configured for applying a contact force at a connection between the respective crucible and the respective distribution assembly. For instance, the first distribution assembly 120A, the second distribution assembly 120B, and the third distribution assembly 120C can be configured as a distribution pipe as described herein.

In particular, according to embodiments which can be combined with any other embodiments described herein, the distribution assembly of the at least one deposition source can be configured as a distribution pipe having a noncircular cross-section perpendicular to the length of the distribution pipe. For example, the cross-section perpendicular to the length of the distribution pipe can be triangular with rounded corners and/or cut-off corners as a triangle. For instance, FIG. 5 shows three distribution pipes having a substantially triangular cross-section perpendicular to the length of the distribution pipes. According to embodiments which can be combined with any other embodiment described herein, each distribution assembly is in fluid communication with the respective evaporation crucible. As exemplarily shown in FIG. 5, the first distribution assembly 120A may be in fluid communication with the first evaporation crucible via a first opening 113A provided between the first distribution assembly and the first evaporation crucible. The second distribution assembly 120B may be in fluid communication with the second evaporation crucible via a second opening 113B provided between the second distribution assembly and the second evaporation crucible. Accordingly, the third distribution assembly 120C may be in fluid communication with the third evaporation crucible via a third opening 113C provided between the third distribution assembly and the third evaporation crucible.

It is to be understood that the description with respect to the features of the at least one deposition source 105 as described with reference to FIGS. 1-3B, may also be applied to the first deposition source 105A, the second deposition source 105B and the third deposition source 105C.

According to embodiments which can be combined with any other embodiment described herein, an evaporator control housing 180 may be provided adjacent to the least one material deposition source, e.g. having a first distribution assembly 120A, a second distribution assembly 120B, and a third distribution assembly 120C, as exemplarily shown in FIG. 5. In particular, the evaporator control housing can be configured to maintain atmospheric pressure therein and is configured to house at least one element selected from the group consisting of: a switch, a valve, a controller, a cooling unit, a cooling control unit, a heating control unit, a power supply, and a measurement device.

According to embodiments which can be combined with any other embodiment described herein, the distribution assembly, particularly the distribution pipe, may be heated by heating elements which are provided inside the distribution assembly. The heating elements can be electrical heaters which can be provided by heating wires, e.g. coated heating wires, which are clamped or otherwise fixed to the inner tubes. With exemplary reference to FIG. 5, a cooling shield 138 can be provided. The cooling shield 138 may include sidewalls which are arranged such that a U-shaped cooling shield is provided in order to reduce the heat radiation towards the deposition area, i.e. a substrate and/or a mask. For example, the cooling shield can be provided as metal plates having conduits for cooling fluid, such as water, attached thereto or provided therein. Additionally, or alternatively, thermoelectric cooling devices or other cooling devices can be provided to cool the cooled shields. Typically, the outer shields, i.e. the outermost shields surrounding the inner hollow space of a distribution pipe, can be cooled.

In FIG. 5, for illustrative purposes, evaporated source material exiting the outlets of the distribution assemblies are indicated by arrows. Due to the essentially triangular shape of the distribution assemblies, the evaporation cones originating from the three distribution assemblies are in close proximity to each other, such that mixing of the source material from the different distribution assemblies can be improved. In particular, the shape of the cross-section of the distribution pipes allow to place the outlets or nozzles of neighboring distribution pipes close to each other. According to some embodiments, which can be combined with other embodiments described herein, a first outlet or nozzle of the first distribution assemblies and a second outlet or nozzle of the second distribution assemblies can have a distance of 50 mm or below, e.g. 30 mm or below, or 25 mm or below, such as from 5 mm to 25 mm. More specifically, the distance of the first outlet or nozzle to a second outlet or nozzle can be 10 mm or below.

As further shown in FIG. 5, a shielding device, particularly a shaper shielding device 137, can be provided, for example, attached to the cooling shield 138 or as a part of the cooling shield. By providing shaper shields, the direction of the vapor exiting the distribution pipe or pipes through the outlets can be controlled, i.e. the angle of the vapor emission can be reduced. According to some embodiments, at least a portion of evaporated material provided through the outlets or nozzles is blocked by the shaper shield. Accordingly, the width of the emission angle can be controlled.

According to another aspect of the present disclosure, a vacuum deposition system 200 is provided, as exemplarily shown in FIG. 6. The vacuum deposition system includes a vacuum deposition chamber 210, a material deposition arrangement 100 according to any of the embodiments described herein in the vacuum deposition chamber 210, and a substrate support 220 configured for supporting a substrate 101 during material deposition.

In particular, the material deposition arrangement 100 can be provided on a track or linear guide 222, as exemplarily shown in FIG. 6. The linear guide 222 may be configured for the translational movement of the material deposition arrangement 100. Further, a drive for providing a translational movement of material deposition arrangement 100 can be provided. In particular, a transportation apparatus for contactless transportation of the material deposition arrangement source may be provided in the vacuum deposition chamber. As exemplarily shown in FIG. 6, the vacuum deposition chamber 210 may have gate valves 215 via which the vacuum deposition chamber can be connected to an adjacent routing module or an adjacent service module. Typically, the routing module is configured to transport the substrate to a further vacuum deposition system for further processing and the service module is configured for maintenance of the material deposition arrangement. In particular, the gate valves allow for a vacuum seal to an adjacent vacuum chamber, e.g. of the adjacent routing module or the adjacent service module, and can be opened and closed for moving a substrate and/or a mask into or out of the vacuum deposition system 200.

With exemplary reference to FIG. 6, according to embodiments which can be combined with any other embodiment described herein, two substrates, e.g. a first substrate 101A and a second substrate 101B, can be supported on respective transportation tracks within the vacuum deposition chamber 210. Further, two tracks for providing masks 333 thereon can be provided. In particular, the tracks for transportation of a substrate carrier and/or a mask carrier may be provided with a further transportation apparatus for contactless transportation of the carriers.

Typically, coating of the substrates may include masking the substrates by respective masks, e.g. by an edge exclusion mask or by a shadow mask. According to typical embodiments, the masks, e.g. a first mask 333A corresponding to a first substrate 101A and a second mask 333B corresponding to a second substrate 101B, are provided in a mask frame 331 to hold the respective mask in a predetermined position, as exemplarily shown in FIG. 6.

As shown in FIG. 6, the linear guide 222 provides a direction of the translational movement of the material deposition arrangement 100. On both sides of the material deposition arrangement 100, a mask 333, e.g. a first mask 333A for masking a first substrate 101A and second mask 333B for masking a second substrate 101B can be provided. The masks can extend essentially parallel to the direction of the translational movement of the material deposition arrangement 100. Further, the substrates at the opposing sides of the evaporation source can also extend essentially parallel to the direction of the translational movement.

With exemplary reference to FIG. 6, a source support 231 configured for the translational movement of the material deposition arrangement 100 along the linear guide 222 may be provided. Typically, the source support 231 supports a crucible 110 and a distribution assembly 120 provided over the evaporation crucible, as schematically shown in FIG. 6. Accordingly, the vapor generated in the evaporation crucible can move upwardly and out of the one or more outlets of the distribution assembly. Accordingly, as described herein, the distribution assembly is configured for providing evaporated material, particularly a plume of evaporated organic material, from the distribution assembly 120 to the substrate 101. It is to be understood that FIG. 6 only shows a schematic representation of the material deposition arrangement 100, and that the material deposition arrangement 100 provided in the vacuum deposition chamber 210 of the vacuum deposition system 200 can have any configuration of the embodiments described herein, as exemplarily described with reference to FIGS. 1 to 5.

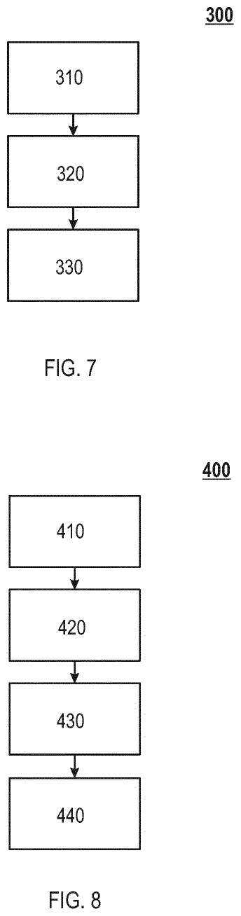

With exemplary reference to FIG. 7, according to a further aspect of the present disclosure, a method 300 for assembling a material deposition arrangement having at least one material deposition source with a crucible and a distribution assembly is provided. In particular, the material deposition arrangement may be a material deposition arrangement 100 according to embodiments described herein. Typically, the method includes inserting (block 310) the crucible 110 into a compartment, e.g. a crucible compartment 115, of the at least one material deposition source 105. Further, the method includes fixing (block 320) a crucible holding arrangement 140 holding the crucible 110 to a wall 111 of the at least one material deposition source 105. Additionally, the method includes applying (block 330) a contact force at a connection 112 between the crucible and the distribution assembly. For instance, the contact force can be a spring force applied by a force application device 130 according to embodiments described herein.

With exemplary reference to FIG. 8, according to a yet further aspect of the present disclosure, a method 400 for exchanging a crucible of a material deposition arrangement having at least one material deposition source with the crucible and a distribution assembly is provided. In particular, the material deposition arrangement may be a material deposition arrangement 100 according to embodiments described herein. The method includes detaching or demounting (block 410) a crucible holding arrangement 140 holding the crucible 110 from a wall 111 of the at least one material deposition source 105. Further, the method includes releasing (block 412) a contact force F_{c} at a connection 112 between the crucible 110 and the distribution assembly 120. Additionally, the method includes removing (block 430) the crucible 110 from a compartment, e.g. a crucible compartment 115, of the at least one material deposition source. Further, the method includes replacing (block 440) the crucible by a new crucible.

Thus, in view of the embodiments described herein, it is to be understood that an improved material deposition arrangement and an improved vacuum deposition system are provided, particularly for OLED manufacturing. Further, by providing a method for assembling a material deposition arrangement as well as a method for exchanging a crucible of a material deposition arrangement as described herein, maintenance of deposition sources can be facilitated.

Further, in the case that the at least one material deposition source includes two or more deposition sources, the material deposition arrangement provides for individual crucible exchange. Moreover, different crucibles having different volumes may be employed. For instance, for deposition of evaporation material of which a relatively small amount is needed, a smaller crucible can be used. Thus, embodiments of the material deposition arrangement as described herein are configured to reduce the cost of ownership, since wastage of source material, particularly expensive organic material, can be reduced.

While the foregoing is directed to embodiments of the disclosure, other and further embodiments of the disclosure may be devised without departing from the basic scope thereof, and the scope thereof is determined by the claims that follow.

In particular, this written description uses examples to disclose the disclosure, including the best mode, and also to enable any person skilled in the art to practice the described subject-matter, including making and using any devices or systems and performing any incorporated methods. While various specific embodiments have been disclosed in the foregoing, mutually non-exclusive features of the embodiments described above may be combined with each other. The patentable scope is defined by the claims, and other examples are intended to be within the scope of the claims if the claims have structural elements that do not differ from the literal language of the claims, or if the claims include equivalent structural elements with insubstantial differences from the literal language of the claims.

1. A material deposition arrangement for depositing a material on a substrate in a vacuum deposition chamber, comprising at least one material deposition source having:
a crucible configured to evaporate the material;
a distribution assembly configured for providing the evaporated material to the substrate; and
a force application device configured for applying a contact force at a connection between the crucible and the distribution assembly.

2. The material deposition arrangement according to claim 1, wherein the at least one material deposition source comprises a crucible holding arrangement configured to be detachably connected to a wall of the at least one material deposition source.

3. The material deposition arrangement according to claim 1, wherein the force application device is connected to the crucible holding arrangement.

4. The material deposition arrangement according to claim 1, wherein the force application device is made of a material having a heat resistance of up to a temperature of at least 200° C.

5. The material deposition arrangement according to claim 1, wherein the force application device includes at least one spring for applying the contact force.

6. The material deposition arrangement according to claim 1, wherein the connection between the crucible and the distribution assembly is provided by a first contact surface of the distribution assembly and a mating second contact surface of the crucible.

7. The material deposition arrangement according to claim 6, wherein the first contact surface is a concave contact surface and wherein the mating second contact surface is a mating convex contact surface.

8. The material deposition arrangement according to claim 2, wherein the crucible holding arrangement includes a mounting assembly configured for mounting the crucible holding arrangement to the wall of the at least one material deposition source.

9. The material deposition arrangement according to claim 2, wherein the crucible holding arrangement includes a heating arrangement configured to provide heat to the crucible for evaporating the material.

10. The material deposition arrangement according to claim 1, wherein the at least one material deposition source comprises a crucible compartment having a closable opening configured for exchanging the crucible.

11. A material deposition arrangement for depositing a material on a substrate in a vacuum chamber, comprising:
a first deposition source having
a first crucible configured to evaporate a first material,
a first distribution assembly configured for providing the evaporated material to the substrate, and
a first force application device configured for applying a contact force at a connection between the first crucible and the first distribution assembly; and
a second deposition source having
a second crucible configured to evaporate a second material,
a second distribution assembly configured for providing the evaporated material to the substrate, and
a second force application device configured for applying a contact force at a connection between the second crucible and the second distribution assembly.

12. A vacuum deposition system, comprising:
a vacuum deposition chamber;
a material deposition arrangement for depositing a material on a substrate in a vacuum deposition chamber, the material deposition arrangement being provided in the vacuum deposition chamber, and the material deposition arrangement comprising at least one material deposition source having:
a crucible configured to evaporate the material;
a distribution assembly configured for providing the evaporated material to the substrate, and a force application device configured for applying a contact force at a connection between the crucible and the distribution assembly; and
a substrate support configured for supporting a substrate during material deposition.

13. A method for assembling a material deposition arrangement having at least one material deposition source with a crucible and a distribution assembly, the method comprising:
inserting the crucible into a compartment of the at least one material deposition source;
fixing a crucible holding arrangement holding the crucible to a wall of the at least one material deposition source; and
applying a contact force at a connection between the crucible and the distribution assembly, wherein the connection between the crucible and the distribution assembly is provided by a first contact surface of the distribution assembly and a mating second contact surface of the crucible.

14. A method for exchanging a crucible of a material deposition arrangement having at least one material deposition source with the crucible and a distribution assembly, the method comprising:
detaching a crucible holding arrangement holding the crucible from a wall of the at least one material deposition source;
releasing a contact force at a connection between the crucible and the distribution assembly, wherein the connection between the crucible and the distribution assembly is provided by a first contact surface of the distribution assembly and a mating second contact surface of the crucible;
removing the crucible from a compartment of the at least one material deposition source; and
replacing the crucible by a new crucible.

15. The method of claim 13, wherein the contact force is a spring force applied by a force application device.

16. The material deposition arrangement according to claim 2, wherein the connection between the crucible and the distribution assembly is provided by a first contact surface of the distribution assembly and a mating second contact surface of the crucible.

17. The material deposition arrangement according to claim 3, wherein the connection between the crucible and the distribution assembly is provided by a first contact surface of the distribution assembly and a mating second contact surface of the crucible.

18. The material deposition arrangement according to claim 16, wherein the first contact surface is a concave contact surface and wherein the mating second contact surface is a mating convex contact surface.

19. The material deposition arrangement according to claim 17, wherein the first contact surface is a concave contact surface and wherein the mating second contact surface is a mating convex contact surface.

20. The material deposition arrangement according to claim 11, wherein the connection between the first crucible and the first distribution assembly is provided by a first contact surface of the first distribution assembly and a mating second contact surface of the first crucible, and wherein the connection between the second crucible and the second distribution assembly is provided by a first contact surface of the second distribution assembly and a mating second contact surface of the second crucible.
